(19) United States
(12) Patent Application Publication
(10) Pub. No.: US 2024/0268079 A1
(43) Pub. Date: Aug. 8, 2024

(54) THERMAL MODULE AND ELECTRONIC DEVICE THEREOF

(71) Applicant: PEGATRON CORPORATION, Taipei City (TW)

(72) Inventor: SHIH-HAO WANG, Taipei City (TW)

(21) Appl. No.: 18/524,537

(22) Filed: Nov. 30, 2023

(30) Foreign Application Priority Data
Feb. 2, 2023 (TW) 112103700

(51) Int. Cl. H05K 7/20; G06F 1/20

(52) U.S. Cl. CPC H05K 7/20454; G06F 1/203; H05K 7/20127

(57) ABSTRACT

The present invention provides a thermal module and an electronic device thereof. The thermal module is used in an electronic device. The electronic device has a shell and a circuit board. A heating element is arranged on the circuit board. The thermal module includes a thermal pad and a heat spreader. The thermal pad is arranged on the circuit board in contact with the heating element. The heat spreader is arranged within the shell and in contact with the thermal pad, and the heat spreader extends along the circuit board and the shell and is bent to conform to an internal shape of the shell.

### TECHNICAL FIELD

The present invention relates to a thermal module and an electronic device thereof, and in particular, to a thermal module and an electronic device thereof that can increase the area of a heat spreader to enhance a heat dissipation effect.

### BACKGROUND

With the rapid development of technology and the advent of the multimedia era, electronic products are becoming increasingly powerful, which also means that more heat energy will be generated. For example, with the rise of 5G, compared with 4G network communication products, 5G network communication products require greater performance requirements for chips but the heat generated is also higher. In the field of related technology, heat dissipation can be accomplished using methods such as fans or heat fins. Fans can enhance heat dissipation through forced convection, but this approach increases costs and may cause fan malfunctions, potentially impacting the fan's lifespan. Heat fins are attached to the surface of a heating element, facilitating the conduction of heat. Convection and radiation can be achieved through the area of multiple fins, thereby transferring heat to the surrounding air for dissipation and cooling the heating element. However, the current form of network communication products comes in various size, and the length of heat fins is limited.

While increasing the length of fins can effectively dissipate heat, the heat source may be overly concentrated on one point on the surface of the casing, causing excessive surface temperature of the casing. Therefore, it is necessary to provide a thermal module and an electronic device thereof to solve shortcomings of the related art.

### SUMMARY

The main objective of the present invention is to provide a thermal module, which can increase the area of a heat spreader to enhance a heat dissipation effect.

Another main objective of the present invention is to provide an electronic device with the above thermal module.

To achieve the above objectives, the thermal module of the present invention is used in an electronic device. The electronic device has a shell and a circuit board. A heating element is arranged on the circuit board. The thermal module includes a thermal pad and a heat spreader. The thermal pad is arranged on the circuit board in contact with the heating element. The heat spreader is arranged within the shell and in contact with the thermal pad, and the heat spreader extends along the circuit board and the shell and is bent to conform to an internal shape of the shell.

The electronic device of the present invention includes a shell, a circuit board, and a thermal module. The circuit board is arranged within the shell and has a heating element. The thermal module includes a thermal pad and a heat spreader. The thermal pad is arranged on the circuit board in contact with the heating element. The heat spreader is arranged within the shell and in contact with the thermal pad, and the heat spreader extends along the circuit board and the shell and is bent to conform to an internal shape of the shell.

### BRIEF DESCRIPTION OF THE DRAWINGS

FIG. 1 is a schematic outside view of an electronic device according to an embodiment of the present invention.

FIG. 2 is a perspective view of a thermal module according to an embodiment of the present invention arranged inside an electronic device.

FIG. 3 is a schematic cross-sectional view of a thermal module according to an embodiment of the present invention arranged inside an electronic device.

FIG. 4 is a schematic diagram of thermal convection formed inside an electronic device according to an embodiment the present invention.

### DETAILED DESCRIPTION

In order to allow examiners to better understand the technical content of the present invention, a preferred embodiment is described below.

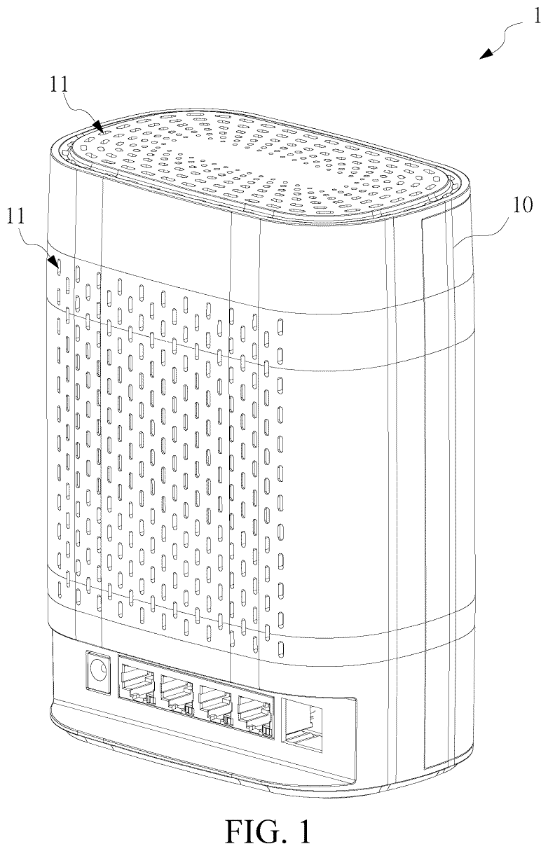

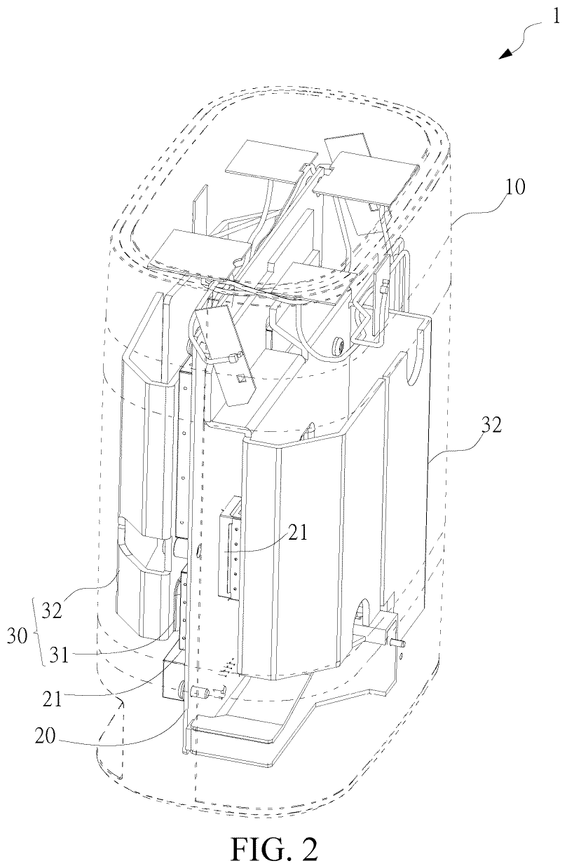

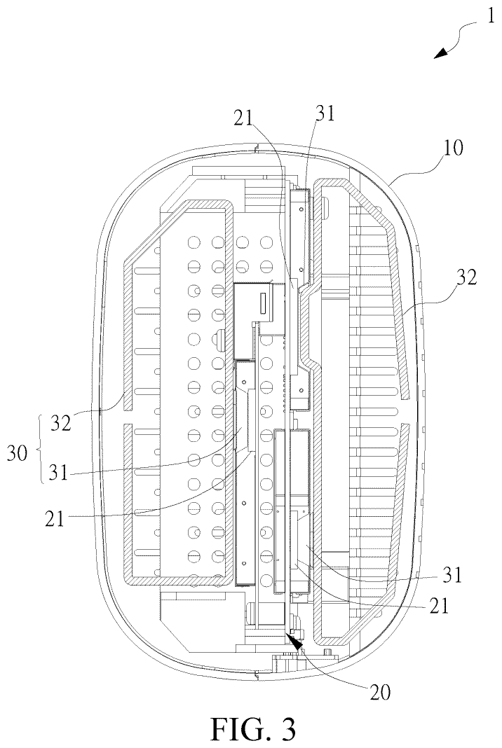

Referring to FIG. 1 to FIG. 3 together, FIG. 1 is a schematic outside view according to an embodiment of an electronic device of the present invention; FIG. 2 is a perspective view of a thermal module according to an embodiment of the present invention arranged inside an electronic device; and FIG. 3 is a schematic cross-sectional view of a thermal module according to an embodiment of the present invention arranged inside an electronic device.

The electronic device 1 of the present invention can be a network communication product, a computer host, or a server host, and the present invention does not limit the type of electronic device 1. The electronic device 1 includes a shell 10, a circuit board 20, and a thermal module 30. The shell 10 may include multiple heat dissipation holes 11 and encloses the circuit board 20 and the thermal module 30. A position of the heat dissipation holes 11 can be arranged on a top or side of the shell 10. The circuit board 20 is arranged within the shell 10 and has a heating element 21. The heating element 21 can be a chip or other electronic components, and the present invention is not limited thereto. The heating element 21 can be arranged on one side or both sides of the circuit board 20, and the present invention does not limit the number of circuit boards 20.

The thermal module 30 includes a thermal pad 31 and a heat spreader 32. The thermal pad 31 can be made of silica gel and added with thermal powder, but the present invention does not limit the material of the thermal pad 31, as long as it has good thermal conductivity, it falls within the scope of protection of the present invention. The thermal pad 31 is arranged on the circuit board 20 in contact with the heating element 21. The heat spreader 32 can be made of a metal material with good thermal conductivity. The heat spreader 32 is arranged within the shell 10 and in contact with the thermal pad 31. The heat spreader 32 extends along the circuit board 20 and the shell 10 in all directions(including up, down, left, and right), and is bent and arranged to conform to an internal shape of the shell 10 to increase the area of the heat spreader 32. The present invention does not limit the number of bent angles in the heat spreader 32. If both sides of the circuit board 20 have heating elements 21, heat spreaders 32 can be arranged on both sides of the circuit board 20, and the present invention does not limit the number of heat spreaders 32. In addition, if there are multiple heating elements 21 on one side of the circuit board 20 that require heat dissipation, the thermal pad 31 can be arranged on each heating element 21, and the heat spreader 32 is in contact with multiple thermal pad 31. In this way, the heat generated by the heating element 21 will be conducted to the heat spreader 32 through the thermal pad 31, and the large area of the heat spreader 32 will achieve preferred heat dissipation effect.

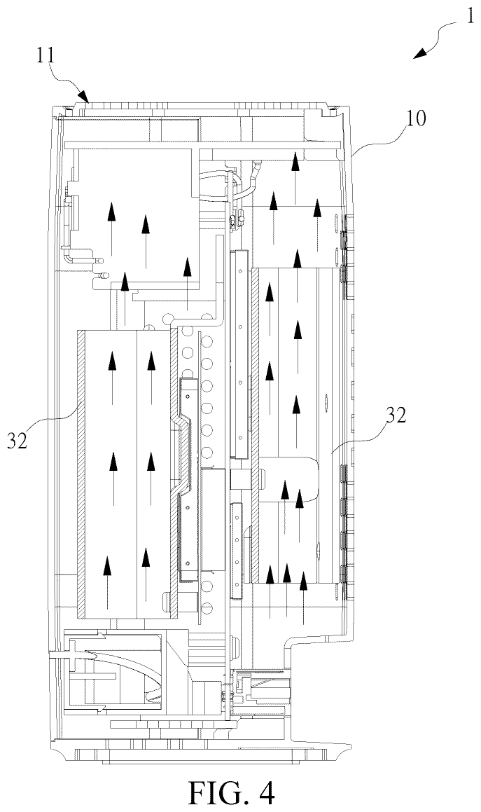

Finally, referring to FIG. 4, which is a schematic diagram of thermal convection formed inside an electronic device according to the present invention.

The bent shape of the heat spreader 32 forms a hollow space inside the shell 10, which is conducive to the formation of heat convection, making it easier for heat to dissipate from the multiple heat dissipation holes 11 on the shell 10.

Therefore, the thermal module 30 of the present invention can effectively conduct the heat generated by the heating element 21 through the large area of the heat spreader 32, improve the overall heat dissipation efficiency of the electronic device 1, and avoid damage caused by excessive temperature of the heating element 21, thereby solving shortcomings of the related art.

It should be noted that the above-described implementations are only preferred embodiments of the present invention, and to avoid redundancy, not all possible combinations of variations are described in detail. However, those skilled in the art should understand that the above modules or components may not be necessary. In order to implement the present invention, other more detailed known modules or components may also be included. Each module or component may be omitted or modified as needed, and there may be other modules or components between any two modules. As long as they do not depart from the basic structure of the present invention, they shall fall within the scope of the claims of the present application.

What is claimed is:

1. A thermal module, used in an electronic device, the electronic device having a shell and a circuit board, a heating element being arranged on the circuit board, and the thermal module comprising:
a thermal pad, arranged on the circuit board in contact with the heating element; and
a heat spreader, arranged within the shell and in contact with the thermal pad, the heat spreader extending along the circuit board and the shell and being bent to conform to an internal shape of the shell.

2. The thermal module according to claim 1, wherein the heat spreader is in contact with a plurality of thermal pads.

3. The thermal module according to claim 1, wherein the bent shape of the heat spreader forms a thermal convection space within the shell.

4. An electronic device, comprising:
a shell;
a circuit board, arranged within the shell and having a heating element; and
a thermal module, comprising:
a thermal pad, arranged on the circuit board in contact with the heating element; and
a heat spreader, arranged within the shell and in contact with the thermal pad, the heat spreader extending along the circuit board and the shell and being bent to conform to an internal shape of the shell.

5. The electronic device according to claim 4, wherein the heat spreader is in contact with a plurality of thermal pads.

6. The electronic device according to claim 4, wherein the bent shape of the heat spreader forms a thermal convection space within the shell.
